(19) United States
(12) Patent Application Publication
(10) Pub. No.: US 2026/0333606 A1
(43) Pub. Date: Oct. 22, 2026

(54) DUAL FUNCTION FIXING ELEMENT AND ASSEMBLY USING SAME

(71) Applicant: Delta Intelligent Building Technologies (Canada) Inc., Surrey (CA)

(72) Inventors: Kang Hao Lee, North Vancouver (CA); Amir Mahani, Richmond (CA)

(21) Appl. No.: 19/181,556

(22) Filed: Apr. 17, 2025

(51) Int. Cl. H05K 7/14

(52) U.S. Cl. CPC H05K 7/1405; H05K 7/1427

(57) ABSTRACT

A dual function fixing element includes a main body, a first engaging protrusion and a second engaging protrusion. The main body has a first surface and a second surface opposite to each other. The first engaging protrusion is disposed on the first surface. The second engaging protrusion is disposed on the second surface. The main body is disposed on a bottom housing of an assembly with the first engaging protrusion protruding toward an internal of the bottom housing and the second engaging protrusion protruding toward an external of the bottom housing. The dual function fixing element simultaneously fixes an intermediate object and a top housing to the bottom housing through engaging the first engaging protrusion with the intermediate object and engaging the second engaging protrusion with the top housing, thereby completing an assembling of the assembly and maintaining the intermediate object between the top housing and the bottom housing.

### FIELD OF THE APPLICATION

The present disclosure relates to a dual function fixing element and an assembly using the same, and more particularly to a dual function fixing element disposed in an assembly for simultaneously fixing two objects in opposite directions so as to achieve the assembling of the assembly.

### BACKGROUND OF THE APPLICATION

Most of the time, there are limitations in the footprint available for packaging PCB within the bottom housing of plastic enclosure. If the top housing is used to secure the PCB to the bottom housing, there is no option to remove the top housing after assembly. If separated fixing structures are employed to respectively secure the PCB and the top housing to the bottom housing, the occupied space and manufacturing cost will be increased.

Therefore, there is a need of providing a dual function fixing element and an assembly using the same to improve the drawbacks above.

### SUMMARY OF THE APPLICATION

An object of the present disclosure is to provide a dual function fixing element and an assembly using the same for addressing the above-discussed deficiencies in the prior arts.

Another object of the present disclosure is to provide a dual function fixing element disposed in an assembly for simultaneously fixing a top housing and an intermediate object to a bottom housing of the assembly.

In accordance with an aspect of the present disclosure, a dual function fixing element applied to an assembly including a bottom housing, an intermediate object and a top housing is provided. The dual function fixing element includes a main body, a first engaging protrusion and a second engaging protrusion. The main body has a first surface and a second surface opposite to each other. The first engaging protrusion is disposed on the first surface. The second engaging protrusion is disposed on the second surface. The main body is disposed on the bottom housing with the first engaging protrusion protruding toward an internal of the bottom housing and the second engaging protrusion protruding toward an external of the bottom housing. The dual function fixing element simultaneously fixes the intermediate object and the top housing to the bottom housing through engaging the first engaging protrusion with the intermediate object and engaging the second engaging protrusion with the top housing, thereby completing an assembling of the assembly and maintaining the intermediate object between the top housing and the bottom housing.

In an embodiment, the main body is configured to provide a first deformation toward the first surface and a second deformation toward the second surface.

In an embodiment, an engagement and a disengagement between the first engaging protrusion and the intermediate object are achieved through the second deformation, and an engagement and a disengagement between the second engaging protrusion and the top housing are achieved through the first deformation.

In an embodiment, the first engaging protrusion is engaged with an edge portion of the intermediate object.

In an embodiment, the intermediate object includes another edge portion opposite to the edge portion, a securing element is located on the bottom housing opposite to the dual function fixing element, and when the intermediate object is assembled to the bottom housing, the intermediate object is in a tilted state where the edge portion is higher than the another edge portion, the another edge portion is fixed by the securing element first, and a downward movement of the edge portion is performed to engage the edge portion under the first engaging protrusion, wherein the downward movement of the edge portion causes the second deformation.

In an embodiment, the first engaging protrusion includes a first slope at an upper portion thereof and extended in a direction gradually toward the internal of the bottom housing from up to down, and the edge portion is downwardly moved along the first slope to cause the second deformation.

In an embodiment, a recess corresponding to the first engaging protrusion is further formed at the edge portion.

In an embodiment, the recess has a recessed distance relative to an end edge of the edge portion, the first engaging protrusion has a first protrusion distance relative to the first surface, and the recessed distance is less than the first protrusion distance.

In an embodiment, when the intermediate object is separated from the bottom housing, the second deformation is manually formed to release an engagement between the first engaging protrusion and the edge portion of the intermediate object.

In an embodiment, the top housing further includes a third engaging protrusion disposed at an inner surface thereof, and the third engaging protrusion is corresponding to and engaged with the second engaging protrusion.

In an embodiment, when the top housing is assembled to the bottom housing, the top housing is in a state substantially parallel to the bottom housing, and a downward movement of the top housing is performed until the third engaging protrusion engages under the second engaging protrusion, wherein the downward movement of the top housing causes the first deformation.

In an embodiment, the second engaging protrusion includes a second slope at an upper portion thereof and extended in a direction gradually toward the external of the bottom housing from up to down, and the third engaging protrusion is downwardly moved along the second slope to cause the first deformation.

In an embodiment, the third engaging protrusion includes a third slope at a lower portion thereof and extended in a direction gradually toward the external of the bottom housing from up to down.

In an embodiment, the second engaging protrusion has a second protrusion distance relative to the second surface, the third engaging protrusion has a third protrusion distance, and the third protrusion distance is less than the second protrusion distance.

In an embodiment, when the top housing is separated from the bottom housing, one side of the top housing which is engaged with the second engaging protrusion is moved up, so that the third engaging protrusion applies an upward force to the second engaging protrusion to cause the first deformation, thereby releasing an engagement between the second engaging protrusion and the top housing.

In an embodiment, an interval is provided between the first engaging protrusion and the intermediate object for providing a space for forming the first deformation when the top housing is separated from the bottom housing.

In an embodiment, the bottom housing includes a sidewall for disposing the main body, and the main body is upwardly extended from the sidewall and substantially parallel to the sidewall, and wherein a height of the first engaging protrusion relative to a bottom surface of the bottom housing is lower than a height of the second engaging protrusion relative to the bottom surface of the bottom housing and higher than a height of an upper edge of the bottom housing relative to the bottom surface of the bottom housing.

In accordance with another aspect of the present disclosure, an assembly is provided. The assembly includes a bottom housing, an intermediate object, a bottom housing and a dual function fixing element described above. The dual function fixing element is disposed on the bottom housing for simultaneously fixing the intermediate object and the top housing to the bottom housing, thereby completing an assembling of the assembly and maintaining the intermediate object between the top housing and the bottom housing.

In an embodiment, the intermediate object includes a plate shape object and is maintained in the assembly in a state substantially parallel to a bottom surface of the bottom housing.

In an embodiment, the intermediate object includes a circuit board, and the top housing and the bottom housing are assembled to maintain the circuit board therein.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is an exploded schematic view showing an assembly adapting a dual function fixing element according to an embodiment of the present disclosure;

FIG. 2 is an enlarged schematic view showing the dual function fixing element according to an embodiment of the present disclosure;

FIG. 3 is a schematic view showing an engagement procedure between a bottom housing and a circuit board of the assembly according to an embodiment of the present disclosure;

FIG. 4 is an enlarged schematic view showing the engagement procedure between the bottom housing and the circuit board according to an embodiment of the present disclosure;

FIG. 5 is an enlarged sectional view showing engagement and disengagement procedures between the circuit board and the bottom housing according to an embodiment of the present disclosure;

FIG. 6 is a schematic view showing an engagement procedure between a top housing and the bottom housing of the assembly according to an embodiment of the present disclosure; and

FIG. 7 is an enlarged sectional view showing engagement and disengagement procedures between the top housing and the bottom housing according to an embodiment of the present disclosure.

### DETAILED DESCRIPTION OF EMBODIMENTS

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed.

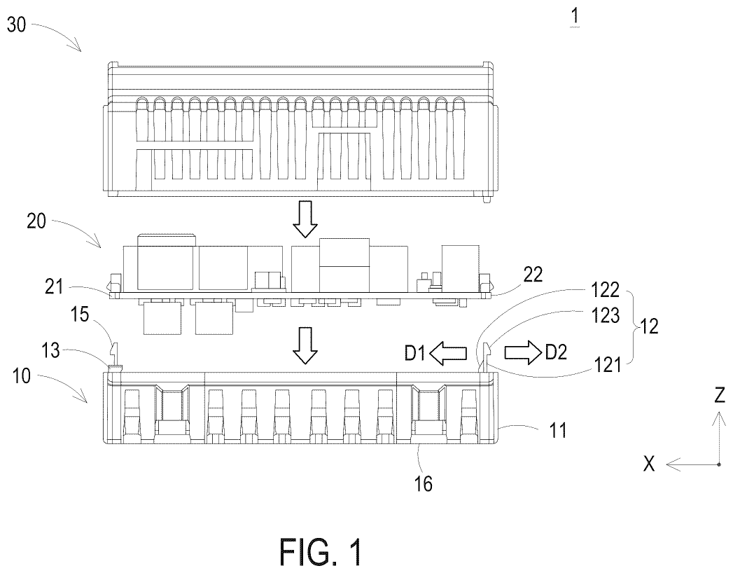

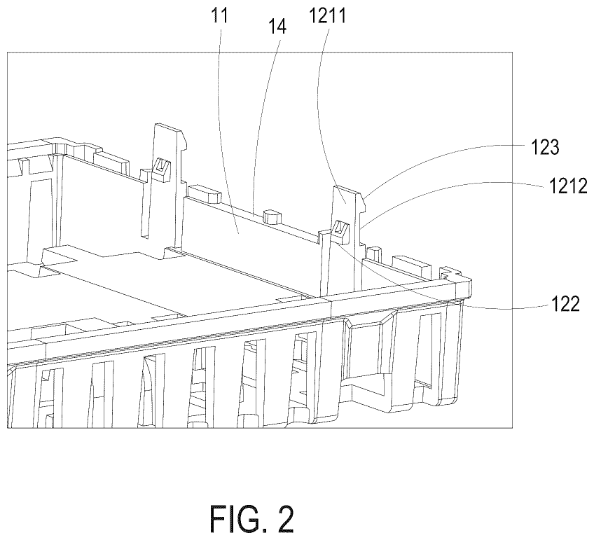

Refer to FIG. 1 and FIG. 2. FIG. 1 is an exploded schematic view showing an assembly adapting a dual function fixing element according to an embodiment of the present disclosure, and FIG. 2 is an enlarged schematic view showing the dual function fixing element according to an embodiment of the present disclosure. An assembly 1 includes a bottom housing 10, an intermediate object 20 and a top housing 30 which are assembled together in sequence, such that the intermediate object 20 is maintained in the assembly 1 in a state substantially parallel to a bottom surface 16 of the bottom housing 10. For example, the assembly 1 can be an electronic device and the intermediate object 20 may include a circuit board with components mounted thereon, but not limited thereto. In some embodiments, the circuit board may be a printed circuit board (PCB). The assembly 1 can be any kind of device assembled by separated housings with an intermediate object, such as a plate shape object, maintained therebetween.

In the present disclosure, in order to smooth the assembling and disassembling of the assembly 1, a dual function fixing element 12 is provided. Generally, when assembling an assembly including a bottom housing, an intermediate object and a top housing, the intermediate object and the top housing are fixed to the bottom housing through different elements, for example, the intermediate object is fixed through screw(s) and the top housing is fixed with the bottom housing through structural engagements. Hence, the assembling procedure is not only complicated but also time consuming. Furthermore, the engaging structures between the bottom housing and the top housing are always designed to be difficultly disassembled for ensuring a secured combination of the assembly, for example, the housing(s) might have to be destroyed for disassembling, which increases the difficulty in maintenance. Accordingly, the dual function fixing element 12 according to the present disclosure used in the assembly 1 is intended to simplify assembling procedure, reduce assembling time and provide the possibility for maintenance while still ensuring the secured combination of the assembly.

The dual function fixing element 12 of the present disclosure is disposed on a sidewall 11 of the bottom housing 10, for example, on an upper edge 14 of the sidewall 11. The dual function fixing element 12 includes a main body 121, a first engaging protrusion 122 and a second engaging protrusion 123. The main body 121 is upwardly extended from the sidewall 11 and substantially parallel to the sidewall 11. The main body 121 includes a first surface 1211 and a second surface 1212 opposite to each other, wherein the first surface 1211 faces an internal of the bottom housing 10 and the second surface 1212 faces an external of the bottom housing 10. The first engaging protrusion 122 is disposed on the first surface 1211, and the second engaging protrusion 123 is disposed on the second surface 1212, wherein the first engaging protrusion 122 is configured to protrude toward the internal of the bottom housing 10, and the second engaging protrusion 123 is configured to protrude toward the external of the bottom housing 10. In other words, the first engaging protrusion 122 and the second engaging protrusion 123 are respectively extended from the main body 121 in opposite directions.

Moreover the first engaging protrusion 122 is located at a height relative to a bottom surface 16 of the bottom housing 10 lower than a height of the second engaging protrusion 123 relative to the bottom surface 16, namely, the first engaging protrusion 122 is lower than the second engaging protrusion 123 in a Z axis direction, and the first engaging protrusion 122 is located at a height relative to the bottom surface 16 higher than a height of the upper edge 14 of the bottom housing 10 relative to the bottom surface 16, namely, the first engaging protrusion 122 is higher than the upper edge 14 in the Z axis direction. Furthermore, since the dual function fixing element 12 is upwardly extended from the sidewall 11 of the bottom housing 10, the upper end thereof is a free end, and thus, through selecting the material thereof, the dual function fixing element 12 can have the flexibility to provide slight deformations. In the embodiment, the main body 121 has a flat shape with the first surface 1211 facing the internal of the housing 10 and the second surface 1212 facing the external of the housing 10, so a first deformation D1 toward the first surface 1211 and a second deformation D2 toward the second surface 1212 in opposite directions can be formed.

For assembling the assembly 1, the intermediate object 10 is assembled to the bottom housing 10 first through engaging with the first engaging protrusion 122, and then, the top housing 30 is also assembled to the bottom housing 20 through engaging with the second engaging protrusion 123. That is, when the assembly 1 is assembled, both the intermediate object 20 and the top housing 30 are simultaneously fixed by the dual function fixing element 12 on the bottom housing 10. On the other hand, for disassembling the assembly 1, the top housing 30 is separated from the bottom housing 10 first through releasing the engagement between the top housing 30 and the second engaging protrusion 123, and then the intermediate object 20 is separated from the bottom housing 10 through releasing the engagement between the intermediate object 20 and the first engaging protrusion 122.

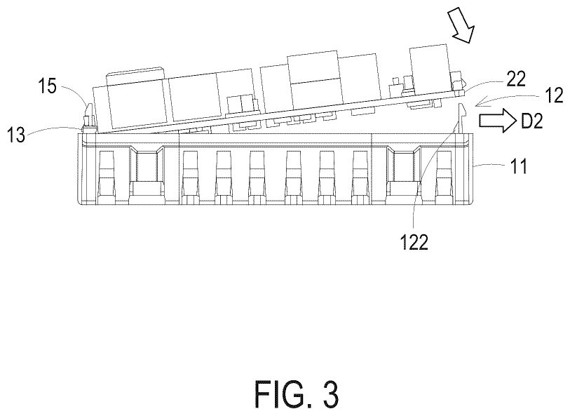

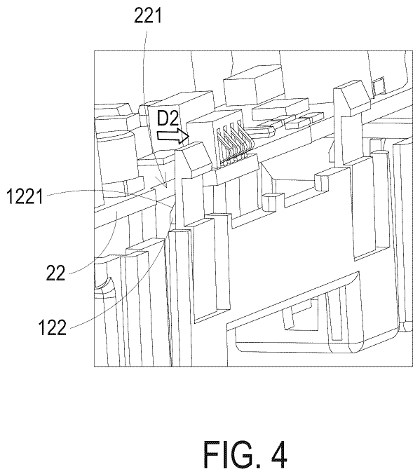

Refer to FIG. 1 to FIG. 5 for details of engagement and disengagement procedures between the intermediate object 20 and the bottom housing 10. When the intermediate object 20 is assembled to the bottom housing 10, the intermediate object 20 is tilted first, so that an edge portion 22 corresponding to the dual function fixing element is higher than another edge portion 21 opposite to the edge portion 22 in the Z axis direction. Accordingly, the edge portion 21 can be slid under and fixed by a securing element 13 on the bottom housing 10 which is at a position opposite to the dual function fixing element 12. Then, the edge portion 22 is moved downward and sliding over the first surface 1211 and the first engaging protrusion 122, thereby being engaged under the first engaging protrusion 122. Consequently, the intermediate object 20 is assembled to the bottom housing 10 through engagements with both the securing element 13 and the first engaging protrusion 122 of the dual function fixing element 12.

When the edge portion 22 is downwardly moved along the first surface 1211 and the first engaging protrusion 122, especially when moved along the first engaging protrusion 122, the dual function fixing element 12 can accordingly form the second deformation D2 due to a pushing force from the edge portion 22 so as to facilitate the passage of the edge portion 22, and then, the dual function fixing element 12 returns to the original position due to the flexibility thereof, thereby achieving the engagement between the first engaging protrusion 122 and the edge portion 22. In order to smooth the downward movement of the edge portion 22, the first engaging protrusion 122 is formed to have a first slope 1221 at the upper portion thereof, where the first slope 1221 is extended in a direction gradually toward the internal of the bottom housing 10 from up to down, so that the downward movement of the edge portion 22 can be guided by the first slope 1221 and the pushing force to form the second deformation D2 can be gradually increased.

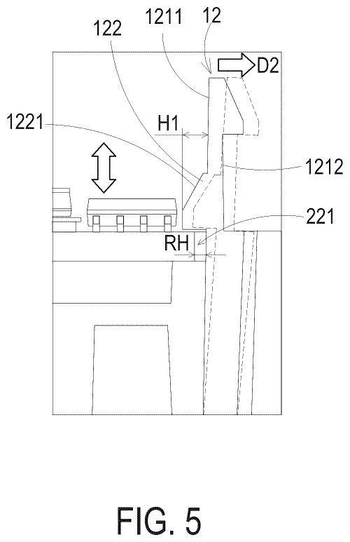

In an embodiment, the intermediate object 20 can further include a recess 221 formed at the edge portion 22 corresponding to the dual function fixing element 12. As shown in FIG. 5, the recess 221 has a recessed distance RH relative to the end edge of the edge portion 22, the first engaging protrusion 122 has a first protrusion distance H1 relative to the first surface 1211, and the recessed distance RH is less than the first protrusion distance H1 of the first engaging protrusion 122. Accordingly, when the edge portion 22 is downwardly moved along the dual function fixing element 12 from up to down, the main body 121 can naturally be accommodated in the recess 221 first. Then, since the recessed distance RH is less than the first protrusion distance H1, the recess 22 will meet the first engaging protrusion 122 at the first slope 1221 and apply the pushing force to the first engaging protrusion 122 as the down movement continues, thereby causing the second deformation D2 to facilitate the passage of the edge portion 22. Also, the first engaging protrusion 122 still can fix the intermediate object 20 in position after the downward movement is finished since the recessed distance RH is less than the first protrusion distance H1. The recess 221 is advantageous that the downward movement of the intermediate object 20 can be achieved with a smaller moving distance of the second deformation D2, which increases the selectivity of material of the dual function fixing element 12 due to a less limitation on the flexibility. In other embodiments, the dual function fixing element 12 also can be manually bent to form the second deformation D2, so as to facilitate the downward movement of the intermediate object 20. Therefore, there is no limitation and can be varied in accordance with practical requirements.

On the other hand, the design of dual function fixing element 12 also facilitates the disengagement between the intermediate object 20 and the bottom housing 10. For separating the intermediate object 20 from the bottom housing 10, the dual function fixing element 12 is manually bent to form the second deformation D2, so as to release the engagement between the first engaging protrusion 122 and the edge portion 22. Under this situation, the edge portion 22 is no longer fixed by the first engaging protrusion 122 and the path for the edge portion 22 to move upward is also exposed, so that the intermediate object 20 can be easily moved out of the bottom housing 10 through lifting up the edge portion 22 and then sliding out the edge portion 21 from the securing element 13, that is, the intermediate object 20 is separated from the bottom housing 10 in a tilted state. After the intermediate object 20 is moved out, the dual function fixing element 12 again returns to the original position due to the flexibility thereof.

Therefore, through the dual function fixing element 12, the intermediate object 20 can be directly fixed to the bottom housing 10 by means of a portion of the bottom housing 10 without employing any separated element(s), such as screw(s), and the engagement and disengagement between the intermediate object 20 and the bottom housing 10 both can be easily achieved without using any tool.

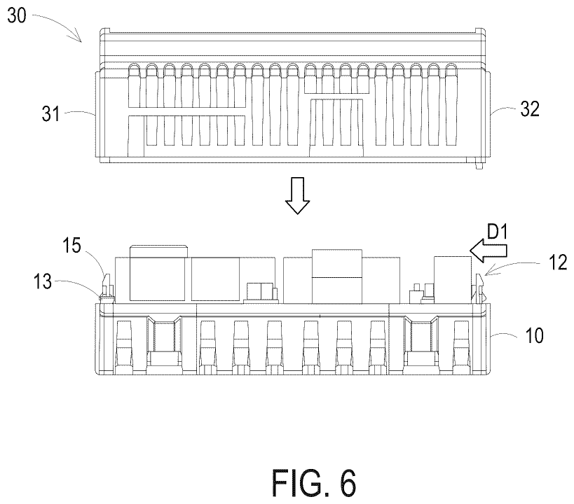

Refer to FIG. 1 to FIG. 2 and FIG. 6 to FIG. 7 for details of engagement and disengagement procedures between the top housing 30 and the bottom housing 10. When assembling the top housing 30 after the intermediate object 10 is assembled, the top housing 30 is moved downward in a state substantially parallel to the bottom housing 10, and the opposite sidewalls 31, 32 of the top housing 30 are respectively engaged with an engaging element 15 and the dual function fixing element 12 at the opposite sides of the bottom housing 10. A third engaging protrusion 322 is formed at the inner surface of the sidewall 32 corresponding to the second engaging protrusion 123 of the dual function fixing element 12 for engaging therewith, and another engaging element (not shown) corresponding to the engaging element 15 is also formed at the inner surface of the sidewall 31, so that the top housing 30 can be stably fixed at the top of the bottom housing 10.

When the top housing 30 is moving downward, due to the pushing force of the third engaging protrusion 322 applied to the second engaging protrusion 123, the dual function fixing element 12 can form the first deformation D1 for facilitating the passage of the third engaging protrusion 322, then the third engaging protrusion 322 keeps moving downward until engaging under the second engaging protrusion 123, and the dual function fixing element 12 returns to the original position due to the flexibility thereof for achieving the engagement between the second engaging protrusion 123 and the third engaging protrusion 322. In order to smooth the downward movement of the top housing 30, the second engaging protrusion 123 is formed to have a second slope 1231 at an upper portion thereof which is extended in a direction gradually toward the external of the bottom housing 10 from up to down, so that the downward movement of the top housing 30 can be guided by the second slope 1231 and the pushing force to form the first deformation D1 can be gradually increased. Further, the third engaging protrusion 322 is formed to have a third slope 3221 at a lower portion thereof which is extended in a direction gradually toward the external of the bottom housing 10 from up to down, for example, corresponding to the second slope 1231, so as to further facilitate the smooth downward movement of the top housing 30.

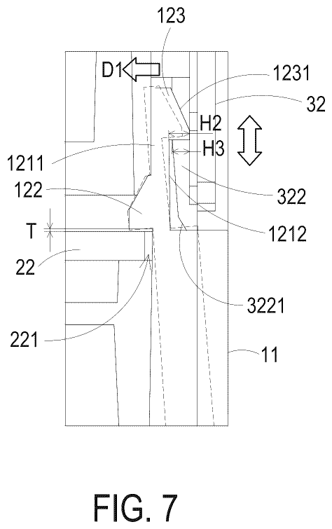

On the other hand, the design of dual function fixing element 12 also facilitates the disengagement between the top housing 30 and the bottom housing 10. For separating the top housing 30 from the bottom housing 10, the top housing 30 is manually lifted up at the sidewall 32, that is, one side of the top housing 30 which is engaged with the second engaging protrusion 123 is moved up to cause the top housing 30 in a tilted state. When the side of the sidewall 32 is lifted up, the third engaging protrusion 322 is also lifted up to apply an upward force to the second engaging protrusion 123. As shown in FIG. 7, the upward force from the third engaging protrusion 322 is only applied at one side of the dual function fixing element 12 adjacent to the sidewall 322, and an interval T at the opposite side of the dual function fixing element 12 is left between the first engaging protrusion 122 and the intermediate object 20 to provide the space for the dual function fixing element 12 to bend, so that the first deformation D1 can therefore be formed. Under this situation, along with the sidewall 32 is gradually lifted up more, the first deformation D1 also gradually increases and finally reaches a point for releasing the engagement between the third engaging protrusion 322 and the second engaging protrusion 123. After the third engaging protrusion 322 is disengaged with the second engaging protrusion 123, the opposite sidewall 31 can then be disengaged with the engaging element 15, thereby completing the disengagement procedure between the top housing 30 and the bottom housing 10.

In an embodiment, for further smoothing the disengagement procedure between the third engaging protrusion 322 and the second engaging protrusion 123, a third protrusion distance H3 of the third engaging protrusion 322 is implemented to be less than a second protrusion distance H2 of the second engaging protrusion 123 relative to the second surface 1212. Accordingly, the upward force is applied at a position more biased to the side of the second engaging protrusion 123 adjacent to the sidewall 322, so that the sidewall 32 can be lifted up more easily, and since the overlapped area between the second engaging protrusion 123 and the third engaging protrusion 322 becomes less, the first deformation D1 for reaching the releasing point also can be reduced.

In addition, advantageously, the first deformation D1 formed as separating the top housing 30 can further apply a fixing force to the edge portion 22 through the first engaging protrusion 122 as the interval T is reduced due to the bending of the dual function fixing element 12 toward the first surface 1211. That is, the greater the upward force applied to the second engaging protrusion 123, the intermediate object 20 is more fixed by the first engaging protrusion 121. Therefore, the engagement between the intermediate object 20 and the bottom housing 10 not only is not influenced by the disengagement between the top housing 30 and the bottom housing 10, but also can be further stabilized thereby.

Therefore, through the dual function fixing element 12, the top housing 30 can be directly fixed to the bottom housing 10 by means of a portion of the bottom housing 10 that is also used by the intermediate object 20, and the engagement and disengagement between the top housing 30 and the bottom housing 10 both can be easily achieved without destroying the top housing and/or using any tool.

In conclusion, through the structural design of the dual function fixing element of the present disclosure, in the assembly, the top housing can be easily removed from the bottom housing after assembling, which is beneficial for easy maintenance of the intermediate object inside the assembly. Moreover, only one dual function fixing element is needed for simultaneously fixing the intermediate object and the top housing in the assembly, so that not only the space can be saved, but also the manufacturing cost can be reduced. Accordingly, the assembly using the dual function fixing element can be assembled in a space-saving and secured manner, and at the same time, also can be conveniently dissembled without losing the integrity of housing(s).

While the disclosure has been described in terms of what is presently considered to be the most practical embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A dual function fixing element, applied to an assembly comprising a bottom housing, an intermediate object, and a top housing, comprising:
a main body having a first surface and a second surface opposite to each other;
a first engaging protrusion disposed on the first surface; and
a second engaging protrusion disposed on the second surface,
wherein the main body is disposed on the bottom housing with the first engaging protrusion protruding toward an internal of the bottom housing and the second engaging protrusion protruding toward an external of the bottom housing; and
wherein the dual function fixing element simultaneously fixes the intermediate object and the top housing to the bottom housing through engaging the first engaging protrusion with the intermediate object and engaging the second engaging protrusion with the top housing, thereby completing an assembling of the assembly and maintaining the intermediate object between the top housing and the bottom housing.

2. The dual function fixing element as claimed in claim 1, wherein the main body is configured to provide a first deformation toward the first surface and a second deformation toward the second surface.

3. The dual function fixing element as claimed in claim 2, wherein an engagement and a disengagement between the first engaging protrusion and the intermediate object are achieved through the second deformation, and an engagement and a disengagement between the second engaging protrusion and the top housing are achieved through the first deformation.

4. The dual function fixing element as claimed in claim 2, wherein the first engaging protrusion is engaged with an edge portion of the intermediate object.

5. The dual function fixing element as claimed in claim 4, wherein the intermediate object comprises another edge portion opposite to the edge portion, a securing element is located on the bottom housing opposite to the dual function fixing element, and when the intermediate object is assembled to the bottom housing, the intermediate object is in a tilted state where the edge portion is higher than the another edge portion, the another edge portion is fixed by the securing element first, and a downward movement of the edge portion is performed to engage the edge portion under the first engaging protrusion, wherein the downward movement of the edge portion causes the second deformation.

6. The dual function fixing element as claimed in claim 4, wherein the first engaging protrusion comprises a first slope at an upper portion thereof and extended in a direction gradually toward the internal of the bottom housing from up to down, and the edge portion is downwardly moved along the first slope to cause the second deformation.

7. The dual function fixing element as claimed in claim 4, wherein a recess corresponding to the first engaging protrusion is further formed at the edge portion.

8. The dual function fixing element as claimed in claim 7, wherein the recess has a recessed distance relative to an end edge of the edge portion, the first engaging protrusion has a first protrusion distance relative to the first surface, and the recessed distance is less than the first protrusion distance.

9. The dual function fixing element as claimed in claim 4, wherein when the intermediate object is separated from the bottom housing, the second deformation is manually formed to release an engagement between the first engaging protrusion and the edge portion of the intermediate object.

10. The dual function fixing element as claimed in claim 2, wherein the top housing further comprises a third engaging protrusion disposed at an inner surface thereof, and the third engaging protrusion of the top housing is corresponding to and engaged with the second engaging protrusion of the dual function fixing element.

11. The dual function fixing element as claimed in claim 10, wherein when the top housing is assembled to the bottom housing, the top housing is in a state substantially parallel to the bottom housing, and a downward movement of the top housing is performed until the third engaging protrusion of the top housing engages under the second engaging protrusion of the dual function fixing element, wherein the downward movement of the top housing causes the first deformation.

12. The dual function fixing element as claimed in claim 10, wherein the second engaging protrusion comprises a second slope at an upper portion thereof and extended in a direction gradually toward the external of the bottom housing from up to down, and the third engaging protrusion is downwardly moved along the second slope to cause the first deformation.

13. The dual function fixing element as claimed in claim 10, wherein the third engaging protrusion comprises a third slope at a lower portion thereof and extended in a direction gradually toward the external of the bottom housing from up to down.

14. The dual function fixing element as claimed in claim 10, wherein the second engaging protrusion has a second protrusion distance relative to the second surface, the third engaging protrusion has a third protrusion distance, and the third protrusion distance is less than the second protrusion distance.

15. The dual function fixing element as claimed in claim 10, wherein when the top housing is separated from the bottom housing, one side of the top housing which is engaged with the second engaging protrusion is moved up, so that the third engaging protrusion applies an upward force to the second engaging protrusion to cause the first deformation, thereby releasing an engagement between the second engaging protrusion and the top housing.

16. The dual function fixing element as claimed in claim 15, wherein an interval is provided between the first engaging protrusion and the intermediate object for providing a space for forming the first deformation when the top housing is separated from the bottom housing.

17. The dual function fixing element as claimed in claim 1, wherein the bottom housing comprises a sidewall for disposing the main body, and the main body is upwardly extended from the sidewall and substantially parallel to the sidewall, and wherein a height of the first engaging protrusion relative to a bottom surface of the bottom housing is lower than a height of the second engaging protrusion relative to the bottom surface of the bottom housing and higher than a height of an upper edge of the bottom housing relative to the bottom surface of the bottom housing.

18. An assembly, comprising:
a bottom housing;
an intermediate object;
a top housing; and
a dual function fixing element as claimed in claim 1 disposed on the bottom housing for simultaneously fixing the intermediate object and the top housing to the bottom housing, thereby completing an assembling of the assembly and maintaining the intermediate object between the top housing and the bottom housing.

19. The assembly as claimed in claim 18, wherein the intermediate object comprises a plate shape object and is maintained in the assembly in a state substantially parallel to a bottom surface of the bottom housing.

20. The assembly as claimed in claim 18, wherein the intermediate object comprises a circuit board, and the top housing and the bottom housing are assembled to maintain the circuit board therein.
